(19) United States
(12) Patent Application Publication
(10) Pub. No.: US 2007/0194296 A1
(43) Pub. Date: Aug. 23, 2007

(54) Light emitting diode and manufacturing method therefor

(75) Inventors: Tetsuroh Murakami, Tenri-Shi (JP); Yukari Inoguchi, Nara-ken (JP); Nobuyuki Watanabe, Nara-shi (JP); Taeko Chiba, Nara-shi (JP)

Correspondence Address: MORRISON & FOERSTER LLP, 1650 TYSONS BOULEVARD, SUITE 400, MCLEAN, VA, 22102, US

(73) Assignee: SHARP KABUSHIKI KAISHA, Osaka-shi (JP)

(21) Appl. No.: 11/709,150

(22) Filed: Feb. 22, 2007

(30) Foreign Application Priority Data
Feb. 22, 2006 (JP) 2006-044920
Nov. 17, 2006 (JP) 2006-311733

(51) Int. Cl. H01L 29/06

(52) U.S. Cl. 257/13

(57) ABSTRACT

A light emitting diode is composed of a p-type GaP substrate 12 and layers laminated on the p-type GaP substrate 12, including a p-type GaP contact layer 13, a p-type AlInP second cladding layer 14, a p-type AlGaInP active layer 15, an n-type AlInP first cladding layer 16 and an n-type AlGaAs current diffusion layer 17. The entire lateral surfaces of the p-type GaP substrate 12 are processed into a roughened state by a dicing blade. The light emitting diode has high light intensity and its surface can be roughened under any circumstances regardless of its material and orientation so that characteristic failures can be prevented from occurring.

### CROSS-REFERENCE TO RELATED APPLICATIONS

This nonprovisional application claims priority under 35 U.S.C. §119(a) on Patent Application No. 2006-044920 filed in Japan on Feb. 22, 2006 and on Patent Application No 2006-311733 filed in Japan on Nov. 17, 2006, the entire contents of which are hereby incorporated by reference.

### BACKGROUND OF THE INVENTION

The present invention relates to a light emitting diode widely used in, for example, lighting, display devices and backlight sources, and to a manufacturing method therefor. More specifically, the present invention relates to a high-intensity light emitting diode having a transparent layer and the like and to a manufacturing method therefor.

Light emitting diodes, which vary in type and are capable of emitting light in wide wavelength bands, are used as display devices of visible light and as light emitting devices of ultraviolet and infrared light. In recent years, the application field of the light emitting diodes are rapidly expanding, in which light sources, in place of fluorescent lamps, display backlights or the like, are drawing attention, and hence the demands for light emitting diodes with higher intensity and higher luminous efficiency are increasing.

In order to meet these demands, techniques such as optimization in design of an emitter layer in the light emitting diode and addition of a reflective layer to the light emitting diode have been implemented so far.

Recently employed is a technique to achieve higher intensity by increasing light extraction efficiency of the light emitting diode by using a transparent substrate as a substrate of the light emitting diode and by roughening the crystal face of the light emitting diode.

Among these techniques, the roughening of the crystal face is widely used since it can be conducted relatively easily.

FIG. 7 is a schematic view showing the configuration of a conventional light emitting diode.

The light emitting diode is composed of a p-type GaP substrate 32 and layers formed on the p-type GaP substrate 32, including a p-type AlInP cladding layer 34, a p-type AlGaInP active layer 35, an n-type AlInP cladding layer 36, an n-type contact layer 37 for transparent electrode and a transparent electrode 39 (see, e.g., JP H04-354382 A).

The p-type GaP substrate 32 has optical transparency to outgoing light from the p-type AlGaInP active layer 35. More specifically, the light emitted from the p-type AlGaInP active layer 35 passes through the p-type GaP substrate 32.

Description is now given of a manufacturing method for the light emitting diode.

First, a wafer is manufactured, which includes the p-type GaP substrate 32, the p-type AlInP cladding layer 34, the p-type AlGaInP active layer 35, the n-type AlInP cladding layer 36, the n-type contact layer 37 for transparent electrode and the transparent electrode 39.

Next, a p-side die bond electrode 31 is formed on one surface of the wafer, while an n-side wire bond pad electrode 38 is formed on the other surface of the wafer, and then scribing and breaking are applied to divide the wafer into a plurality of chips.

Finally, the lateral surfaces of the chips (the surfaces obtained by dividing the wafer) are roughened by chemical processing to obtain completed light emitting diodes. The chemical processing is herein applied with use of hydrochloric acid and the like.

Thus-manufactured light emitting diodes have double hetero structure in which the active layer 35 is put between the cladding layers 34 and 36, thereby achieving increase in luminous efficiency of the active layer 35.

Moreover, since the p-type GaP substrate 32 has optical transparency to the outgoing light from the active layer 35, it becomes possible to extract light from the GaP substrate 32.

Further, since the lateral surfaces of the light emitting diodes are subjected to roughening processing, it becomes possible to extract light from the lateral surfaces of the light emitting diodes.

Another conventional light emitting diode is a light emitting diode with its lateral surfaces and top surface being roughened by chemical processing (see, e.g., JP 2004-356279 A, JP 2005-327979 A, and JP 2003-209283 A).

FIG. 14 is a schematic view showing the configuration of another conventional light emitting diode.

The light emitting diode, as shown in FIG. 14, is composed of a p-type GaP substrate 232 and layers formed below the p-type GaP substrate 232, including a p-type AlInP second cladding layer 234, a p-type AlGaInP active layer 235, an n-type AlInP first cladding layer 236, and an n-type AlGaAs current diffusion layer 237. The surface of the p-type GaP substrate 232 on the upper side of the drawing constitutes the top surface of the light emitting diode.

It is to be noted that in FIG. 14, reference numeral 231 denotes a p-side wire bond pad electrode, while reference numeral 238 denotes an n-side die bond electrode.

The processing to roughen the lateral surfaces of the conventional light emitting diode and the processing to roughen the lateral surfaces and the top surface of another conventional light emitting diode are chemical processing, which exploits the fact that etching rates of crystal are different depending on its orientation, or which employs chemicals with reactivity strong enough to roughen the etching surface on purpose.

However, exploiting the fact that the etching rates of crystal are different depending on its orientation gives rise to a problem in which the types and the orientations of crystal that can be roughened are limited.

Employing chemicals with strong reactivity gives rise to a problem in which a part of the semiconductor layer constituting a chip is etched to its inner section and thereby causes such problems as characteristic failure.

Particularly in the case where the light emitting diode has a transparent layer such as the p-type GaP substrates 32 and 232 and where the surface of the transparent layer to be a light extraction section is a mirror surface, the outgoing light from the emitter layer is reflected by the surface, its multiple reflection increases light loss, and hence the effect of extracting the outgoing light from the emitter layer to the outside is decreased. Therefore, the roughening technique is an important technique for achieving high light intensity.

### SUMMARY OF THE INVENTION

An object of the present invention is to provide a high-intensity light emitting diode and a manufacturing method therefor, capable of using the roughening technique under any circumstances regardless of materials and crystal orientations of the light emitting diode so that characteristic failures can be prevented from occurring.

In order to achieve the above object, there is provided a light emitting diode, comprising:

an emitter layer made of a semiconductor layer;

an intermediate layer made of a semiconductor layer placed on the emitter layer; and

a transparent layer having transparency to outgoing light from the emitter layer and placed on the intermediate layer,

wherein a part of or an entire surface of the transparent layer is processed into a roughened state by a dicing blade.

According to the above-structured light emitting diode, a part of or the entire surface of the transparent layer is processed into a roughened state, so that outgoing light from the emitter layer can effectively be extracted from a part or the entire surface of the transparent layer and hence high intensity can be achieved.

Moreover, since a part of or the entire surface of the transparent layer is processed into a roughened state by the dicing blade, any material can be used as a material of the transparent layer.

Moreover, since a part of or the entire surface of the transparent layer is processed into a roughened state by the dicing blade, the transparent layer is free from excessive etching by strong chemicals, which can prevent characteristic failure from occurring.

It is to be noted that the transparent layer can employ any formation method, component material and orientation.

In one embodiment of the invention, the surface processed into a roughened state by the dicing blade is lateral surfaces of the transparent layer.

According to the light emitting diode of the above embodiment, a part of or the entire lateral surface of the transparent layer is processed into a roughened state, so that outgoing light from the emitter layer can effectively be extracted from a part or the entire lateral surface of the transparent layer and hence high light intensity can be achieved.

Moreover, since a part of or the entire lateral surface of the transparent layer is processed into a roughened state by the dicing blade, the transparent layer can employ any material and orientation.

Moreover, since a part of or the entire lateral surface of the transparent layer is processed into a roughened state by the dicing blade, the transparent layer is free from excessive etching by strong chemicals, which can prevent characteristic failure from occurring.

It is to be noted that the transparent layer can employ any formation method, component material and orientation. Of course, this holds true with regard to the emitter layer.

In one embodiment of the invention, the surface processed into a roughened state by the dicing blade is a top surface of the transparent layer.

The top surface of the transparent layer herein refers to the surface of the transparent layer on the opposite side of the intermediate layer.

According to the light emitting diode of the above embodiment, a part of or the entire top surface of the transparent layer is processed into a roughened state, so that outgoing light from the emitter layer can effectively be extracted from a part or the entire top surface of the transparent layer and hence high light intensity can be achieved.

Moreover, since a part of or the entire top surface of the transparent layer is processed into a roughened state by the dicing blade, any material can be used as a material of the transparent layer.

Moreover, since a part of or the entire top surface of the transparent layer is processed into a roughened state by the dicing blade, the transparent layer is free from excessive etching by strong chemicals, which can prevent characteristic failure from occurring.

It is to be noted that the transparent layer can employ any formation method, component material and orientation.

In one embodiment of the invention, a part of or entire lateral surfaces of the emitter layer is processed into a roughened state by the dicing blade.

According to the light emitting diode in the embodiment, a part of or the entire lateral surfaces of the emitter layer is processed into a roughened state by the dicing blade, so that outgoing light from the emitter layer can effectively be extracted from a part or the entire lateral surfaces of the emitter layer and hence higher light intensity can be achieved.

In one embodiment of the invention, the transparent layer is a substrate glued to the intermediate layer.

In one embodiment of the invention, the transparent layer is an epitaxial growth layer or a substrate for epitaxial growth use.

In one embodiment of the invention, the emitter layer is made of a compound containing at least two or more elements out of Al, Ga, As, In, P, Zn, Se, Te, Sn, Si, C, Ti, Mg, Cd, B, N, O and S.

In one embodiment of the invention, the transparent layer is made of a compound containing at least two or more elements out of Al, Ga, As, In, P, Zn, Se, Te, Sn, Si, C, Ti, Mg, Cd, B, N, O and S.

In one embodiment of the invention, the emitter layer is made of AlGaInP, and wherein the transparent layer is made of GaP.

There is also provided a manufacturing method for a light emitting diode, comprising the steps for:

manufacturing a wafer including an emitter layer made of a semiconductor layer, an intermediate layer made of a semiconductor layer placed on the emitter layer, and a transparent layer having transparency to outgoing light from the emitter layer and placed on the intermediate layer; and

processing a part of or an entire surface of the transparent layer into a roughened state by a dicing blade.

According to the above-structured manufacturing method for the light emitting diode, a part of or the entire surface of the transparent layer is processed into a roughened state by the dicing blade, so that a part of or the entire surface of the transparent layer can be roughened easily at low costs regardless of the material and the orientation of the transparent layer.

This makes it possible to achieve the high-intensity light emitting diode with ease at low costs.

Moreover, since a part of or the entire surface of the transparent layer is processed into a roughened state by the dicing blade, the transparent layer can employ any material and orientation.

Moreover, since a part of or the entire surface of the transparent layer is processed into a roughened state by the dicing blade, the transparent layer is free from excessive etching by strong chemicals, which can prevent characteristic failure from occurring.

Moreover, since the roughening processing of the transparent layer is performed by the dicing blade, it becomes possible to omit such steps as chemical processing steps and overcoating steps required for the roughening processing through chemical processing.

The dicing blade makes it possible to apply the roughening processing not only to semiconductor crystal but also to amorphous materials such as glass, quartz and sapphire, as well as to apply the roughening processing to those materials resistant to chemicals.

In one embodiment of the invention, the surface processed into a roughened state by a dicing blade is lateral surfaces of the transparent layer.

According to the above-structured manufacturing method for the light emitting diode, a part of or the entire lateral surface of the transparent layer is processed into a roughened state by the dicing blade, so that a part of or the entire lateral surface of the transparent layer can be roughened easily at low costs regardless of the material and the orientation of the transparent layer.

This makes it possible to achieve the high-intensity light emitting diode with ease at low costs.

Moreover, since a part of or the entire lateral surface of the transparent layer is processed into a roughened state by the dicing blade, the transparent layer can employ any material and orientation.

Moreover, since a part of or the entire lateral surface of the transparent layer is processed into a roughened state by the dicing blade, the transparent layer is free from excessive etching by strong chemicals, which can prevent characteristic failure from occurring.

Moreover, since the roughening processing of the transparent layer is performed by the dicing blade, it becomes possible to omit such steps as chemical processing steps and overcoating steps required for the roughening processing through chemical processing.

The dicing blade makes it possible to apply the roughening processing not only to semiconductor crystal but also to amorphous materials such as glass, quartz and sapphire, as well as to apply the roughening processing to those materials resistant to chemicals.

In one embodiment of the invention, the surface processed into a roughened state by a dicing blade is top surfaces of the transparent layer.

The top surface of the transparent layer herein refers to the surface of the transparent layer on the opposite side of the intermediate layer.

According to the above-structured manufacturing method for the light emitting diode, a part of or the entire top surface of the transparent layer is processed into a roughened state by the dicing blade, so that a part of or the entire top surface of the transparent layer can be roughened easily at low costs regardless of the material and the orientation of the transparent layer.

This makes it possible to achieve the high-intensity light emitting diode with ease at low costs.

Moreover, since a part of or the entire top surface of the transparent layer is processed into a roughened state by the dicing blade, the transparent layer can employ any material and orientation.

Moreover, since a part of or the entire top surface of the transparent layer is processed into a roughened state by the dicing blade, the transparent layer is free from excessive etching by strong chemicals, which can prevent characteristic failure from occurring.

Moreover, since the roughening processing of the transparent layer is performed by the dicing blade, it becomes possible to omit such steps as chemical processing steps and overcoating steps required for the roughening processing through chemical processing.

The dicing blade makes it possible to apply the roughening processing not only to semiconductor crystal but also to amorphous materials such as glass, quartz and sapphire, as well as to apply the roughening processing to those materials resistant to chemicals.

In one embodiment of the invention, before the wafer is diced into a form of devices, a part of or entire lateral surfaces of the transparent layer are roughened through half dicing or pre-dicing by the dicing blade.

According to the manufacturing method for a light emitting diode in the embodiment, before the wafer is diced into the shape of devices, a part of or an entire surface of the transparent layer is roughened through half dicing or pre-dicing by the dicing blade, so that electrical and optical measurement tests can be applied to light emitting diodes which are in the state of being included in the wafer and roughened. In other words, optical tests can be performed over the light emitting diodes which are in the state very close to the form of devices.

It is to be noted that if the roughening processing is applied to the light emitting diode after execution of the optical tests, a correlation between the light intensity detected by the tests and the light intensity of a light emitting diode chip in the form of the device (completed state) is lost.

In one embodiment of the invention, after the wafer is diced into a form of devices, a part of or entire surfaces of the transparent layer are processed into a roughened state by the dicing blade.

According to the manufacturing method for a light emitting diode in the embodiment, after the wafer is diced into the form of devices, a part of or an entire surface of the transparent layer is processed into a roughened state by the dicing blade, so that the roughening processing by the dicing blade is not necessary at the time of dicing the wafer into the form of devices and hence the freedom of manufacturing steps can be increased.

In one embodiment of the invention, a size of an abrasive grain of the dicing blade is 2 μm or more.

According to the manufacturing method for a light emitting diode in the embodiment, there is a correlation between the size of an abrasive grain of the dicing blade and the light output of a chip. Consequently, setting the size at 2 μm or more makes it possible to obtain the roughened surface exhibiting good efficiency of extracting outgoing light from the emitter layer to the outside.

Moreover, in the case of removing a mechanically damaged layer formed by the dicing blade, setting the size of an abrasive grain of the dicing blade at 4 μm or more makes it possible to maintain the roughened state as it is even after the damaged layer is removed.

Generally, materials with extremely high hardness such as diamond are used as an abrasive grain of the dicing blade for mechanical formation of the roughened state, and therefore the roughened state can easily be formed in any material without being affected by feasibility of the roughened state and orientation dependency.

For example, the roughened state can be formed by the dicing blade even in the case of a GaP substrate. A high-output red light emitting device can be obtained by using this GaP substrate as a transparent substrate, using an AlGaInP layer as an emitter layer, and by roughening a part or the entire lateral surfaces of the transparent substrate by the dicing blade.

It should naturally be understood that the method with use of the dicing blade is applicable not only to the case where a GaP substrate is mounted on an emitter layer made of AlGaInP but also to any light emitting diode having a transparent layer, such as, in the case where a GaN/InGaN layer is mounted on a sapphire substrate, in the case where an AlGaInP layer and a GaN/InGaN layer are mounted on a glass substrate or a SiC substrate, and in the case where an AlGaAs layer (having a composition transparent to red color) is epitaxially grown on a GaAs substrate and an emitter layer is laminated in sequence.

The light emitting diode in the present invention can achieve high intensity by roughening the light emitting surface, and particularly the light emitting diode with a transparent layer placed therein can achieve high light intensity of the device as it can form the roughened state regardless of materials.

It also becomes possible to omit chemical processing after dicing the wafer into chips, thereby allowing simplification of the manufacturing process.

### BRIEF DESCRIPTION OF THE DRAWINGS

The present invention will become more fully understood from the detailed description given hereinbelow and the accompanying drawings which are given by way of illustration only, and thus are not intended to limit the present invention, and wherein:

FIG. 1 is a schematic view showing the configuration of a light emitting diode in a first embodiment of the present invention;

FIG. 2A is a schematic view for explaining MOCVD crystal growth of the light emitting diode shown in FIG. 1;

FIG. 2B is a schematic view for explaining formation of GaP junction structure in the light emitting diode shown in FIG. 1;

FIG. 3A is a view showing the grinded surface state of a p-type GaP substrate diced by a dicing blade having an abrasive grain size of 4 μm;

FIG. 3B is a view showing the grinded surface state of a p-type GaP substrate diced by a dicing blade having an abrasive grain size of 1 μm;

FIG. 4A is an image view showing optical paths inside a light emitting diode having mirror-polished lateral surfaces;

FIG. 4B is an image view showing optical paths inside a light emitting diode having roughened lateral surfaces;

FIG. 5A is a graph view showing an orientation characteristic of the light emitting diode having roughened lateral surfaces;

FIG. 5B is a graph view showing an orientation characteristic of the light emitting diode having mirror-polished lateral surfaces;

FIG. 6 is a graph view showing difference in output of a light emitting diode caused by difference in abrasive grain size of a blade;

FIG. 7 is a schematic view showing the configuration of a conventional light emitting diode;

FIG. 8 is a schematic view showing the configuration of a light emitting diode in a second embodiment of the present invention;

FIG. 9A is a schematic view for explaining MOCVD crystal growth of the light emitting diode shown in FIG. 8;

FIG. 9B is a schematic view for explaining formation of GaP junction structure in the light emitting diode shown in FIG. 8;

FIG. 10A is a view showing the grinded surface state of a p-type GaP substrate diced by a dicing blade having an abrasive grain size of 4 μm;

FIG. 10B is a view showing the grinded surface state of a p-type GaP substrate diced by a dicing blade having an abrasive grain size of 1 μm;

FIG. 11A is an image view showing optical paths inside a light emitting diode having a mirror-polished top surface;

FIG. 11B is an image view showing optical paths inside a light emitting diode having a mirror-polished top surface;

FIG. 12 is a graph view showing difference in output of a light emitting diode caused by difference in abrasive grain size of a blade;

FIG. 13 is a schematic view showing one aspect in the case where a part of the top surface is diced; and

FIG. 14 is a schematic view showing the configuration of an another conventional light emitting diode.

### DETAILED DESCRIPTION OF THE INVENTION

Hereinbelow, the light emitting diode of the present invention will be described in detail in conjunction with the embodiments with reference to the drawings.

### First Embodiment

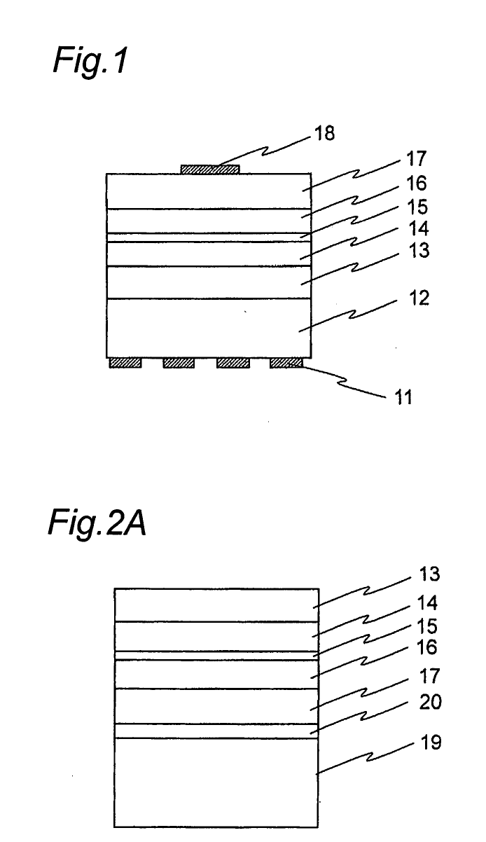

FIG. 1 is a schematic view showing the configuration of a light emitting diode in a first embodiment of the present invention.

The light emitting diode is composed of a p-type GaP substrate 12 and layers laminated on the p-type GaP substrate 12, including a p-type GaP contact layer 13, a p-type AlInP second cladding layer 14, a p-type AlGaInP active layer 15, an n-type AlInP first cladding layer 16 and an n-type AlGaAs current diffusion layer 17. It is to be noted that the p-type AlGaInP active layer 15 is an example of the emitter layer. The p-type GaP substrate 12 is also an example of the transparent layer. The p-type GaP contact layer 13 and the p-type AlInP second cladding layer 14 are respectively examples of the intermediate layer.

The entire lateral surfaces of the p-type GaP substrate 12, the p-type GaP contact layer 13, the p-type AlInP second cladding layer 14, the p-type AlGaInP active layer 15, the n-type AlInP first cladding layer 16 and the n-type AlGaAs current diffusion layer 17 are processed into a roughened state.

On the n-type AlGaAs current diffusion layer 17, an unshown ohmic contact layer made of AuSi/Au is formed, and on the ohmic contact layer, an n-side wire bond pad electrode (n-side electrode) 18 is formed. Herein, the n-side wire bond pad electrode 18 is formed into generally a disc shape.

Under the p-type GaP substrate 12, a p-side ohmic contact layer electrode 11 made of AuBe is formed. Herein, the p-side ohmic contact layer electrode 11 is formed like a dot on the back surface of the p-type GaP substrate 12 (the surface opposite to the p-type AlGaInP active layer 15-side surface).

The above-configured light emitting diode is manufactured as shown below.

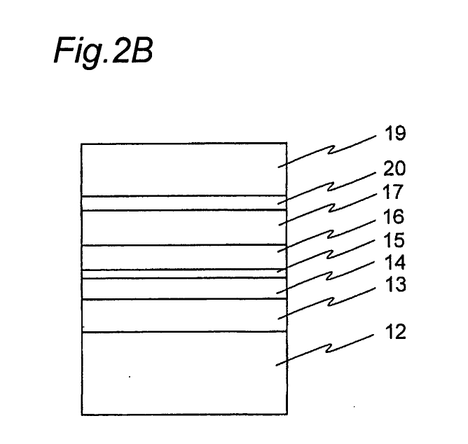

First, as shown in FIG. 2A, an n-type GaAs buffer layer 20, an n-type AlGaAs current diffusion layer 17 with a layer thickness of 3 μm, an n-type AlInP first cladding layer 16 with a layer thickness of 1 μm, a p-type AlGaInP active layer 15 with a layer thickness of 0.5 μm, a p-type AlInP second cladding layer 14 with a layer thickness of 1 μm, and a p-type GaP contact layer 13 with a layer thickness of 3 μm are sequentially laminated on an n-type GaAs substrate 19 by MOCVD (Metal Organic Chemical Vapor Deposition) method.

Next, as shown in FIG. 2B, a p-type GaP substrate 12, which is prepared separately, is brought into contact with the p-type GaP contact layer 13, and a load is applied to the p-type GaP substrate 12. Then, in this state, the p-type GaP substrate 12 and the p-type GaP contact layer 13 are put in a hydrogen atmosphere at high temperature so as to be joined.

Next, the n-type GaAs substrate 19 and the n-type GaAs buffer layer 20 are removed by an ammonium-based etchant.

Next, as shown in FIG. 1, AuBe is deposited on the back surface of the p-type GaP substrate 12 by evaporation method and is patterned into polka dots and then being alloyed. Thus, the p-side ohmic contact layer electrode 11 made of AuBe can be obtained.

Next, AuSi/Au and the material of the n-side wire bond pad electrode 18 are deposited on the surface of the n-type AlGaAs current diffusion layer 17 by evaporation method. The AuSi/Au and the material are patterned into generally a disc shape and alloyed. Thus, the ohmic contact layer and the n-side wire bond pad electrode 18 can be obtained.

Next, a wafer including the p-type GaP substrate 12, the p-type GaP contact layer 13, the p-type AlInP second cladding layer 14, the p-type AlGaInP active layer 15, the n-type AlInP first cladding layer 16 and the n-type AlGaAs current diffusion layer 17 is divided through dicing, so that light emitting diode chips can be obtained. The dicing was performed with use of a dicing blade with an abrasive grain size of 4 μm.

Next, in order to remove a mechanically damaged layer formed by the dicing, the dicing surface is etched by a compound liquid of sulfuric acid, hydrogen peroxide and water. In this case, it is sufficient for the damaged layer to be removed away only very thin amount by etching. The roughened state of the lateral surface of the chip is intact because a part of the damaged layer, is etched away by very thin amount. In order to maintain the roughened state with ease and certainty, dicing should be performed with use of a dicing blade with an abrasive grain size larger than 4 μm. In this case, the light extraction effect can be increased compared to the case of using the dicing blade with an abrasive grain size of 4 μm.

Conventionally, dicing was performed with use of a dicing blade with an abrasive grain size of 1 μm or less, so that the surface grinded by the dicing blade was put in the state close to mirror and then was subjected to roughening processing through HCl processing or with use of HCl dilution.

The dicing blade, which is composed of a disc-like base and abrasive grains such as diamond grains attached thereto through electrodeposition and the like, is rotated at high speed to dice semiconductor materials. The smaller the abrasive grain size of the dicing blade becomes, the more smooth the grinded surface is finished with less chips (chipping). The larger abrasive grain size causes chipping, i.e., the side portions of an upper surface of the chip formed by the dicing blade is chipped.

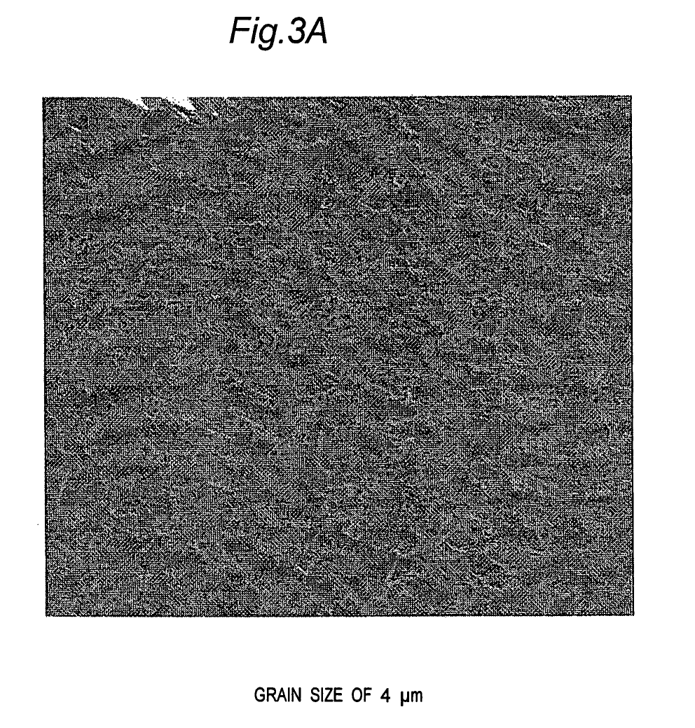

FIG. 3A shows the grinded surface state in the case where the p-type GaP substrate 12 is diced with use of a dicing blade with an abrasive grain size of 4 μm. FIG. 3B shows the grinded surface state in the case where the p-type GaP substrate 12 is diced with use of a dicing blade with an abrasive grain size of 1 μm.

As is clear from FIG. 3A and FIG. 3B, the state of the diced surface (grinded surface) is changed considerably by the grain size of the dicing blade.

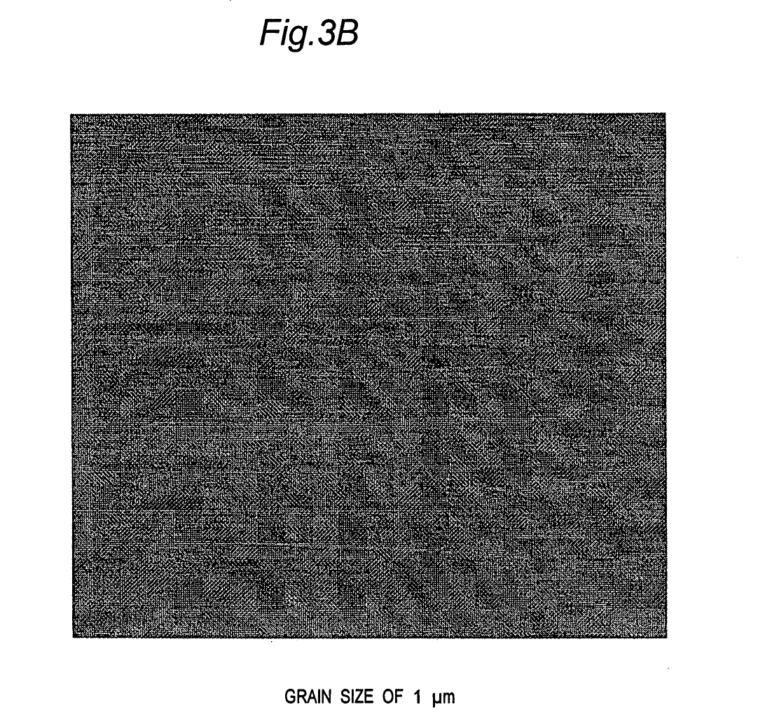

Such roughening processing is performed in order to increase the light extraction efficiency. Without the roughening processing on the lateral surfaces of the chip, as shown in FIG. 4A, a part of emitted light from the emitter layer inside the chip is reflected by the lateral surfaces of the chip and trapped inside the chip, and during repeated multiple reflection, the light is absorbed or attenuated inside crystal, or reenters the emitter layer and is absorbed therein.

By roughening the lateral surfaces of the chip, as shown in FIG. 4B, an incoming angle of emitted light from the emitter layer inside the chip, with respect to the lateral surfaces of the chip, is changed so that a percentage of the light, going out of the chip without being reflected to the inside of the chip, is increased and hence the light extraction efficiency is enhanced.

Since a plane equivalent to (111) orientation in GaP is low in reaction rate for HCl processing, the equivalent plane appears on the surface and creates a roughened state from a macroscopic standpoint, while projections and depressions of several nm are formed on the processed surface from a microscopic standpoint. In addition, since the reaction rate is extremely low, the HCl processing needs to be performed for a long period of time. Moreover, since the emitter layer is etched through HCl processing, it is necessary to perform the HCl processing after the emitter layer is protected. Furthermore, depending on the lattice plane of the chip, good roughened state is hard to obtain.

In the case of the first embodiment, the dicing blade with an abrasive grain size of 4 μm is used, so that projections and depressions of several nm are formed on the grinded surface by the dicing blade, and the grinded surface is put in a roughened state.

In the case of using the dicing blade with an abrasive grain size larger than 4 μm, chipping increases slightly, but the HCl processing and the chip surface coating step can be simplified, so that production efficiency can be enhanced.

Moreover, the output of the light emitting diode in the first embodiment is adequate enough as it is equal to or higher than the output of roughened chips by chemical processing. More specifically, the output of a light emitting diode, which was diced by a dicing blade with a small abrasive grain size and then was not subjected to removal of mechanically damaged layer due to the dicing, was 6.5 mW. The output of a light emitting diode, which was diced by a dicing blade with a small abrasive grain size and then was subjected to removal of mechanically damaged layer by the dicing, was 8.0 mW. As is the first embodiment, the output of a light emitting diode, which was diced by a dicing blade with a large abrasive grain size and then was not subjected to removal of mechanically damaged layer due to the dicing, was 8.8 mW.

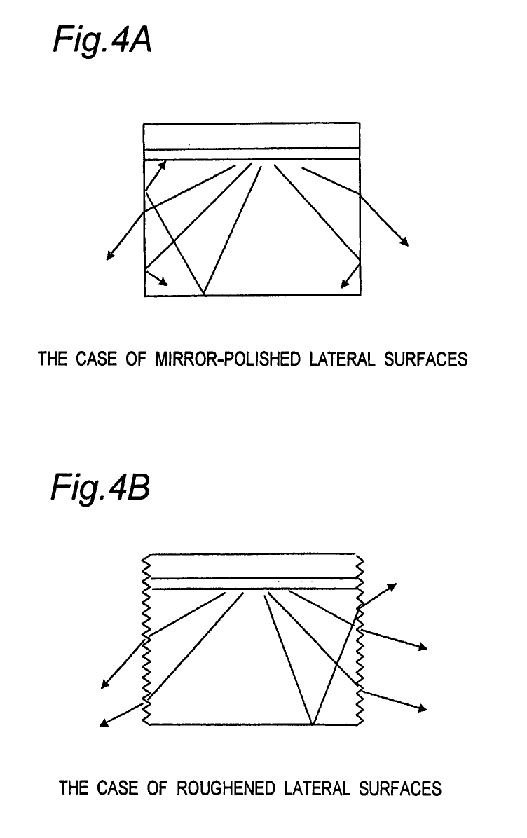

FIG. 5A shows a graph view showing an orientation characteristic of a light emitting diode diced by a dicing blade with an abrasive grain size of 4 μm. FIG. 5B shows a graph view showing an orientation characteristic of a light emitting diode diced by a dicing blade with an abrasive grain size of 1 μm.

As is clear from FIG. 5A and FIG. 5B, light components outgoing from the lateral surfaces are larger in the light emitting diode diced by the dicing blade with an abrasive grain size of 4 μm than in the light emitting diode diced by the dicing blade with an abrasive grain size of 1 μM.

Accordingly, in order to confirm a relationship between abrasive grain sizes of dicing blades and optical outputs, an experiment was conducted to confirm optical outputs of a light emitting diode diced with use of dicing blades each having an abrasive grain size of 0.5 μm, 3 μm, 5 μm and 7 μm.

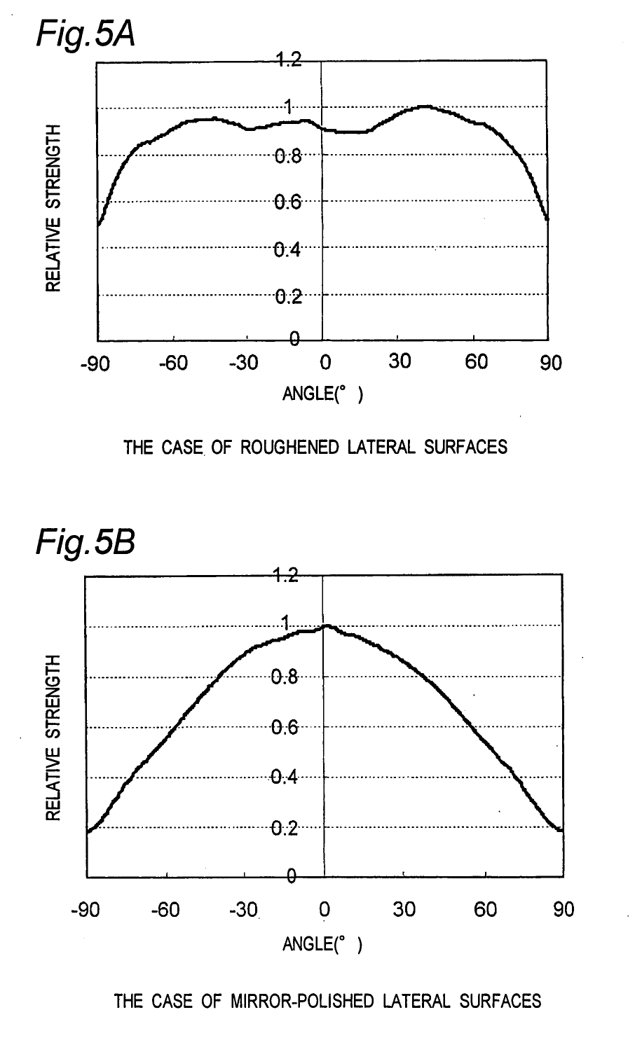

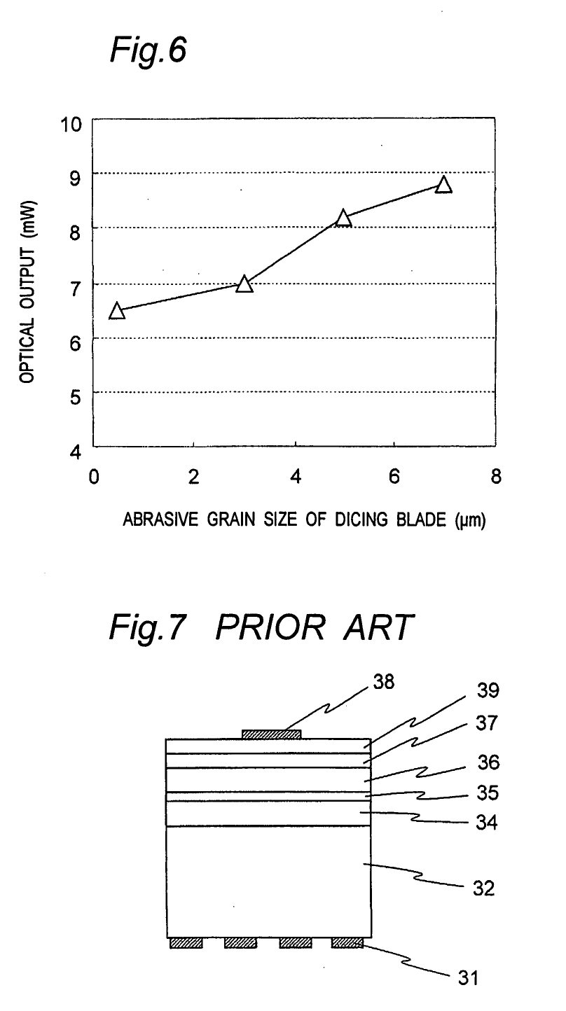

FIG. 6 shows the result of the experiment.

As is clear from FIG. 6, the size of abrasive grains of dicing blades and optical outputs of the light emitting diode are in a correlation, and particularly the optical outputs of the light emitting diode diced by the dicing blades having an abrasive grain size of 5 μm and 7 μm are increased.

The above experiment indicated that use of the dicing blade with larger abrasive grain size increases the optical output of the light emitting diode. However, in the case of using a dicing blade with an abrasive grain size of 8 μm or larger, a phenomenon in which the life of the dicing blade is enormously shortened has been observed, and this suggests that the abrasive grain size of the dicing blade for use in manufacturing of light emitting diodes is preferably 2 μm or larger and 8 μm or smaller in consideration of costs and productivity.

Although in the first embodiment, the entire lateral surfaces of the light emitting diode are processed into a roughened state, only a part of one lateral surface of the p-type GaP substrate 12 may be processed into a roughened state, or a part of the lateral surfaces of the p-type GaP substrate 12 may be processed into a roughened state.

Although in the first embodiment, the p-type AlGaInP active layer 15 is used as an example of the emitter layer, the emitter layer may be made of a compound containing at least two or more elements among Al, Ga, As, In, P, Zn, Se, Te, Sn, Si, carbon, Ti, Mg, Cd, boron, nitrogen, oxygen and sulfur.

Although in the first embodiment, the p-type GaP substrate 12 is used as an example of the transparent layer, the transparent layer may be made of a compound containing at least two or more elements among Al, Ga, As, In, P, Zn, Se, Te, Sn, Si, C, Ti, Mg, Cd, B, N, O and S.

Although the light emitting diode in the first embodiment is configured to have an AlGaInP emitter layer and a GaP substrate, the light emitting diode of the present invention is not limited to the configuration and may be configured to have, for example, an AlGaAs emitter layer and a GaAs substrate. This configuration provides the same effect as the first embodiment. It is to be noted that in this configuration, light emitted from the AlGaAs emitter layer passes through the GaAs substrate.

Although in the first embodiment, a wafer is divided into a plurality of chips (light emitting diodes) only by a dicing blade, the wafer may be subjected to half dicing or pre-dicing by a dicing blade and then divided into a plurality of chips.

Although in the first embodiment, the lateral surfaces of a chip are processed into a roughened state in the dicing step for dividing a wafer into a plurality of chips, it is also possible to process the lateral surfaces of a chip into a roughened state by a dicing blade not in the dicing step but after the dicing step.

### Second Embodiment

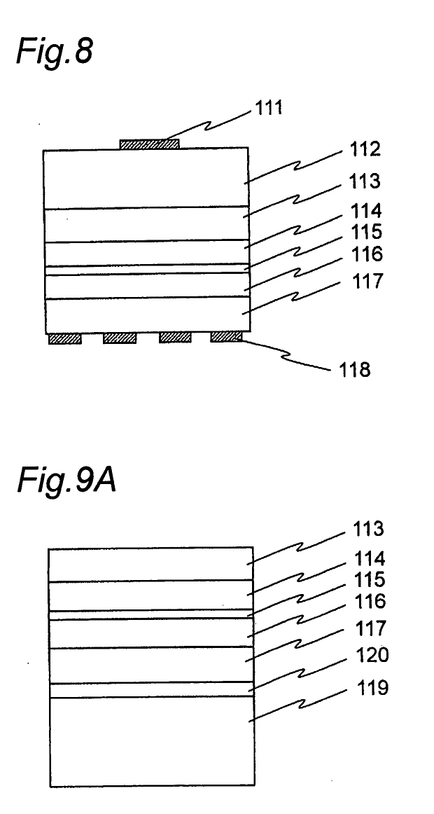

FIG. 8 is a schematic view showing the configuration of a light emitting diode in a second embodiment of the present invention.

The light emitting diode is composed of a p-type GaP substrate 112, a p-type GaP contact layer 113, a p-type AlInP second cladding layer 114, a p-type AlGaInP active layer 115, an n-type AlInP first cladding layer 116, and an n-type AlGaAs current diffusion layer 117. It is to be noted that the p-type AlGaInP active layer 115 is an example of the emitter layer. The p-type GaP substrate 112 is an example of the transparent layer. Also, the p-type GaP contact layer 113 and the p-type AlInP second cladding layer 114 are respectively examples of the intermediate layer.

In the p-type GaP substrate 112, the entire surface opposite to the side of the p-type GaP contact layer 113 is processed into a roughened state. In the p-type GaP substrate 112, the entire surface generally vertical to the said surface is also processed into a roughened state. In other words, the entire top surface and lateral surfaces of the p-type GaP substrate 112 are processed into a roughened state

On the p-type GaP substrate 112, a p-side wire bond pad electrode (p-side electrode) 111 is formed. Herein, the p-side wire bond pad electrode 111 is formed into generally a disc shape. Between the p-side wire bond pad electrode 111 and the p-type GaP substrate 112, an unshown p-side ohmic contact layer made of AuBe is formed. The p-side ohmic contact layer is formed into generally the same shape as the p-side wire bond pad electrode 111. More specifically, a part of the top surface of the p-type GaP substrate 112 (the surface of the p-type GaP substrate 112 opposite to the side of the p-type GaP contact layer 113) is exposed without being coated with the p-side ohmic contact layer and the p-side wire bond pad electrode 111.

Under the n-type AlGaAs current diffusion layer 117, an n-side die bond electrode 118 made of AuSi/Au is formed. Herein, the n-side die bond electrode 118 is formed like a dot on the back surface of the n-type AlGaAs current diffusion layer 117 (the surface of the n-type AlGaAs current diffusion layer 117 opposite to the side of the n-type AlInP first cladding layer 116).

The light emitting diode of the above configuration is manufactured as shown below.

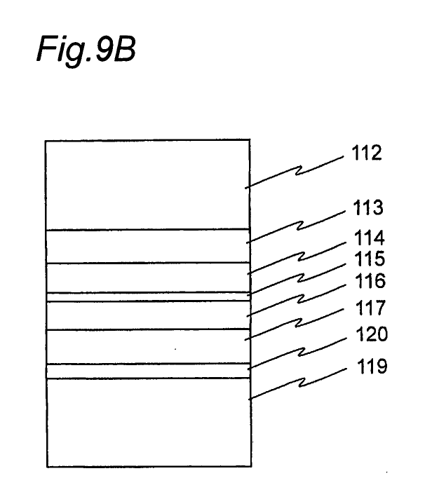

First, as shown in FIG. 9A, an n-type GaAs buffer layer 120, an n-type AlGaAs current diffusion layer 117 with a layer thickness of 20 μm, an n-type AlInP first cladding layer 116 with a layer thickness of 1 μm, a p-type AlGaInP active layer 115 with a layer thickness of 0.5 μm, a p-type AlInP second cladding layer 114 with a layer thickness of 1 μm, and a p-type GaP contact layer 113 with a layer thickness of 3 μm are laminated in sequence on an n-type GaAs substrate 119 by MOCVD (Metal Organic Chemical Vapor Deposition) method.

Next, as shown in FIG. 9B, a p-type GaP substrate 112, which is prepared separately, is brought into contact with the p-type GaP contact layer 113, and a load is applied to the p-type GaP substrate 112. Then, in this state, the p-type GaP substrate 112 and the p-type GaP contact layer 113 are put in a hydrogen atmosphere at high temperature so as to be joined.

Next, the n-type GaAs substrate 119 and the n-type GaAs buffer layer 120 are removed by an ammonium-based etchant.

Next, a dicing blade is run so as to scrape a portion of up to 5 μm depth from the top surface of the p-type GaP substrate 112 (the surface of the p-type GaP substrate 112 opposite to the side of the p-type GaP contact layer 113). This roughens the entire top surface of the p-type GaP substrate 112. Herein, the dicing blade with a blade width of 50 μm and an abrasive grain size of 4 μm was used.

Next, as shown in FIG. 8, AuBe and a material of the p-side wire bond pad electrode 111 are deposited on the roughened top surface of the p-type GaP substrate 112 by evaporation method and are patterned into generally a disc shape and then being alloyed. Thus, the p-side ohmic contact layer and the p-side wire bond pad electrode 111 can be obtained.

Next, AuSi/Au is deposited on the bottom surface of the n-type AlGaAs current diffusion layer 17 (the surface of the n-type AlGaAs current diffusion layer 117 opposite to the side of the n-type AlInP first cladding layer 116) by evaporation method. The AuSi/Au is patterned into polka dots and then being alloyed. Thus, the n-side die bond electrode 118 can be obtained.

Next, a wafer including the p-type GaP substrate 112, the p-type GaP contact layer 113, the p-type AlInP second cladding layer 114, the p-type AlGaInP active layer 115, the n-type AlInP first cladding layer 116 and the n-type AlGaAs current diffusion layer 117 is divided through dicing, so that light emitting diode chips can be obtained.

Next, in order to remove a mechanically damaged layer formed by the dicing, the diced top surface and lateral surfaces of light emitting diodes are etched by a compound liquid of sulfuric acid, hydrogen peroxide and water. In this case, only an extremely thin layer should be etched away for the removal of the damaged layer.

The dicing blade, which is composed of a disc-like base and abrasive grains such as diamond grains attached thereto through electrodeposition and the like, is rotated at high speed to dice semiconductor materials. The smaller the abrasive grain size of the dicing blade becomes, the more smooth the grinded surface is finished with less chips (chipping). The larger abrasive grain size causes chipping.

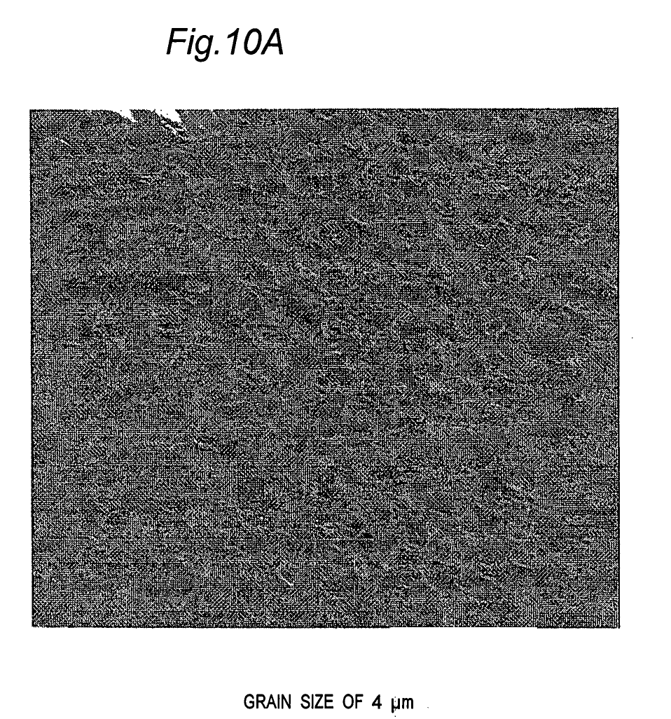

FIG. 10A shows the grinded surface state in the case where a p-type GaP substrate is diced with use of a dicing blade with an abrasive grain size of 4 μm. FIG. 10B shows the grinded surface state in the case where a p-type GaP substrate is diced with use of a dicing blade with an abrasive grain size of 1 μm.

As is clear from FIG. 10A and FIG. 10B, the state of the diced surface (grinded surface) is changed considerably by the grain size of the dicing blade.

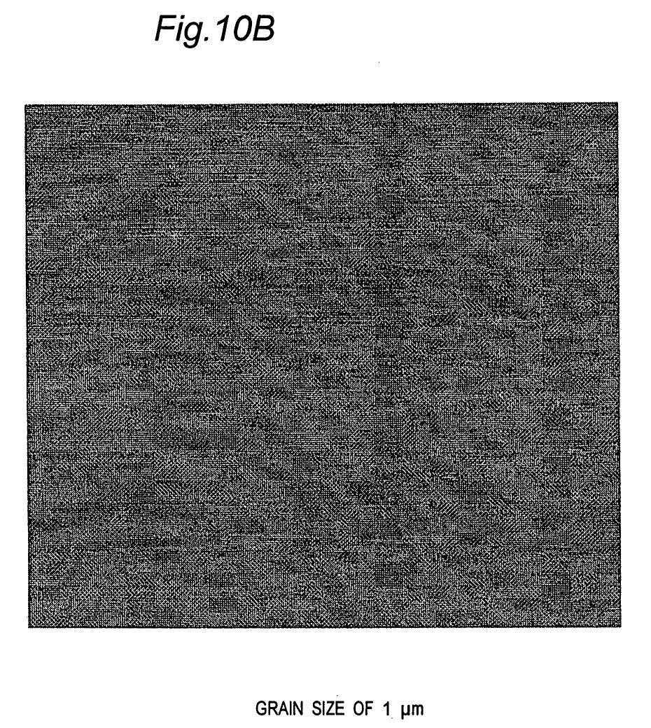

Such roughening processing is performed in order to increase the light extraction efficiency. Without the roughening processing on the top surface of the chip, as shown in FIG. 11A, a part of emitted light from the emitter layer inside the chip is reflected by the top surface of the chip and trapped inside the chip, and during repeated multiple reflection, the light re-enters into the emitter layer and is attenuated therein.

By roughening the top surface of the chip, as shown in FIG. 11B, an incoming angle of emitted light from the emitter layer inside the chip, with respect to the top surface of the chip, is changed so that a percentage of the light, going out of the chip without being reflected to the inside of the chip, is increased and hence the light extraction efficiency is enhanced.

In the case of the second embodiment, the dicing blade with an abrasive grain size of 4 μm is used, so that projections and depressions of several nm are formed on the grinded surface by the dicing blade, and the grinded surface is put in a roughened state.

Moreover, the output of the light emitting diode in the second embodiment is increased from the output of the light emitting diode without roughening processing. More specifically, the output of a light emitting diode having mirror-finished top surface and lateral surfaces was 8.0 mW. As in the second embodiment, the output of the light emitting diode, whose top surface and lateral surfaces were roughened with use of a dicing blade with a large abrasive grain size, was 8.5 mW.

In order to confirm a relationship between the abrasive grain size of dicing blades and optical outputs, an experiment was conducted to confirm optical outputs of a light emitting diode diced with use of dicing blades each having an abrasive grain size of 0.5 μm, 3 μm, 5 μm and 7 μm.

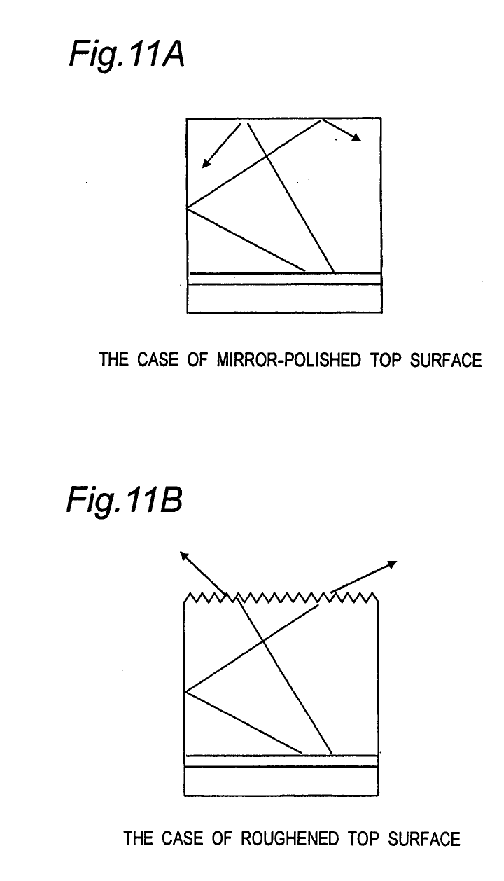

FIG. 12 shows the result of the experiment.

As is clear from FIG. 12, the size of abrasive grains of dicing blades and optical outputs of the light emitting diode are in a correlation, and particularly the optical outputs of the light emitting diode diced by the dicing blades having an abrasive grain size of 5 μm and 7 μm are increased.

The above experiment indicated that use of the dicing blade with larger abrasive grain size increases the optical output of the light emitting diode. However, in the case of using a dicing blade with an abrasive grain size of 8 μm or larger, a phenomenon in which the life of the dicing blade is enormously shortened has been observed, and this suggests that the abrasive grain size of the dicing blade for use in manufacturing of light emitting diodes is preferably 2 μm or larger and 8 μm or smaller in consideration of costs and productivity.

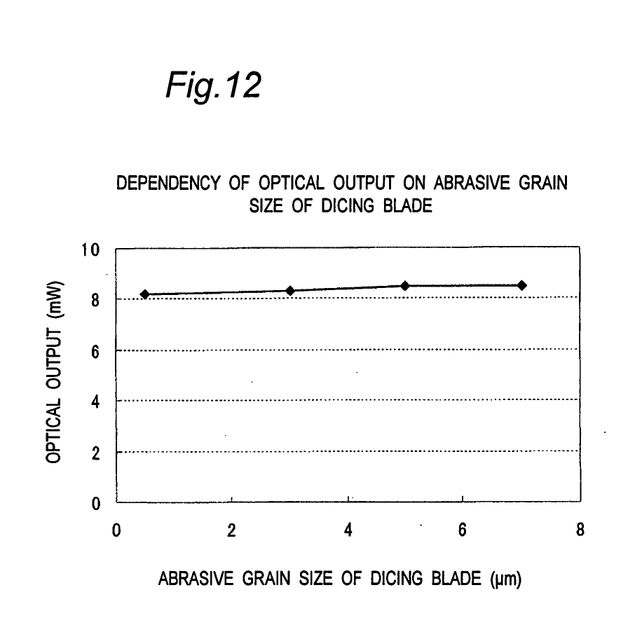

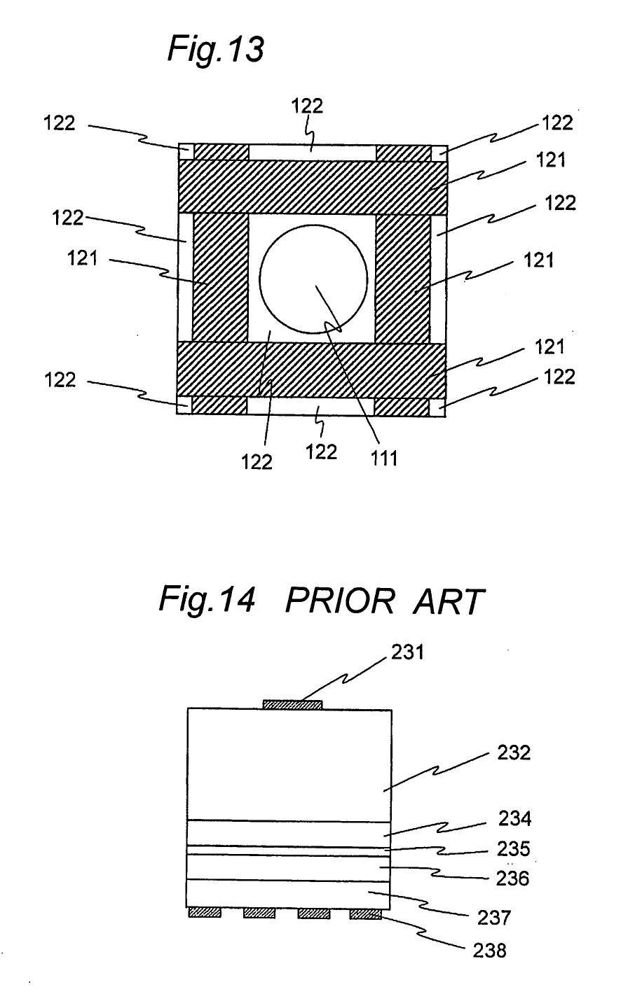

Although in the second embodiment, the entire top surface of the light emitting diode is processed into a roughened state, only a part of the top surface of the p-type GaP substrate 12 may be processed into a roughened state. More specifically, as shown in FIG. 13, a roughened region 121 may be formed on a portion of the top surface of the p-type GaP substrate, the portion other than a formation region of the p-side wire bond pad electrode 111. In the case where the roughened region 121 is formed, the flatness of the p-side wire bond pad electrode 111 is increased, which can ensure excellent wire bonding strength. It is to be noted that reference numeral 122 in FIG. 13 denotes a mirror surface region.

Although in the second embodiment, the lateral surfaces and the top surface of the light emitting diode are processed into roughened state, only the top surface of the light emitting diode may be roughened. In the case where only the top surface of the light emitting diode is roughened, the entire top surface may be roughened or only a part of the top surface may be roughened.

Although in the second embodiment, the p-type AlGaInP active layer 115 is used as an example of the emitter layer, the emitter layer may be made of a compound containing at least two or more elements among Al, Ga, As, In, P, Zn, Se, Te, Sn, Si, carbon, Ti, Mg, Cd, boron, nitrogen, oxygen and sulfur.

Although in the second embodiment, the p-type GaP substrate 112 is used as an example of the transparent layer, the transparent layer may be made of a compound containing at least two or more elements among Al, Ga, As, In, P, Zn, Se, Te, Sn, Si, C, Ti, Mg, Cd, B, N, O and S.

Although the light emitting diode in the second embodiment is configured to have an AlGaInP emitter layer and a GaP substrate, the light emitting diode of the present invention is not limited to the configuration and may be configured to have, for example, an AlGaAs emitter layer and a GaAs substrate. This configuration provides the same effect as the first embodiment. It is to be noted that in this configuration, light emitted from the AlGaAs emitter layer passes through the GaAs substrate.

Although in the second embodiment, a wafer is divided into a plurality of chips (light emitting diodes) only by a dicing blade, the wafer may be subjected to half dicing or pre-dicing by a dicing blade and then divided into a plurality of chips.

Although in the second embodiment, the lateral surfaces of a chip are processed into a roughened state in the dicing step for dividing a wafer into a plurality of chips, it is also possible to process the lateral surfaces of a chip into a roughened state by a dicing blade not in the dicing step but after the dicing step.

The present invention may be structured by combining the description of the first embodiment and the description of the second embodiment as appropriate.

In the light emitting diode in the present invention, a part of or the entire lateral surfaces of the emitter layer may be processed into a roughened state.

The light emitting diode in the present invention may have an optically transparent substrate made of glass and other materials.

The light emitting diode in the present invention may have a light transmission layer made through crystal growth, or have an InGaN made on a sapphire substrate through epitaxial growth.

In other words, the present invention is applicable to light emitting diodes of any configuration composed of an emitter layer and a transparent layer for passing the light emitted from the emitter layer.

Embodiments of the invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

1. A light emitting diode, comprising:
an emitter layer made of a semiconductor layer;
an intermediate layer made of a semiconductor layer placed on the emitter layer; and
a transparent layer having transparency to outgoing light from the emitter layer and placed on the intermediate layer,
wherein a part of or an entire surface of the transparent layer is processed into a roughened state by a dicing blade.

2. The light emitting diode according to claim 1,
wherein the surface processed into a roughened state by the dicing blade is lateral surfaces of the transparent layer.

3. The light emitting diode according to claim 1,
wherein the surface processed into a roughened state by the dicing blade is a top surface of the transparent layer.

4. The light emitting diode according to claim 1,
wherein a part of or entire lateral surfaces of the emitter layer is processed into a roughened state by the dicing blade.

5. The light emitting diode according to claim 1,
wherein the transparent layer is a substrate glued to the intermediate layer.

6. The light emitting diode according to claim 1,
wherein the transparent layer is an epitaxial growth layer or a substrate for epitaxial growth use.

7. The light emitting diode according to claim 1,
wherein the emitter layer is made of a compound containing at least two or more elements out of Al, Ga, As, In, P, Zn, Se, Te, Sn, Si, C, Ti, Mg, Cd, B, N, O and S.

8. The light emitting diode according to claim 1,
wherein the transparent layer is made of a compound containing at least two or more elements out of Al, Ga, As, In, P, Zn, Se, Te, Sn, Si, C, Ti, Mg, Cd, B, N, O and S.

9. The light emitting diode according to claim 1,
wherein the emitter layer is made of AlGaInP, and
wherein the transparent layer is made of GaP.

10. A manufacturing method for a light emitting diode, comprising the steps for:
manufacturing a wafer including an emitter layer made of a semiconductor layer, an intermediate layer made of a semiconductor layer placed on the emitter layer, and a transparent layer having transparency to outgoing light from the emitter layer and placed on the intermediate layer; and
processing a part of or an entire surface of the transparent layer into a roughened state by a dicing blade.

11. The manufacturing method for a light emitting diode according to claim 10,
wherein the surface processed into a roughened state by a dicing blade is lateral surfaces of the transparent layer.

12. The manufacturing method for a light emitting diode according to claim 10,
wherein the surface processed into a roughened state by a dicing blade is top surfaces of the transparent layer.

13. The manufacturing method for a light emitting diode according to claim 11,
wherein before the wafer is diced into a form of devices, a part of or entire lateral surfaces of the transparent layer are roughened through half dicing or pre-dicing by the dicing blade.

14. The manufacturing method for a light emitting diode according to claim 11,
wherein after the wafer is diced into a form of devices, a part of or entire surfaces of the transparent layer are processed into a roughened state by the dicing blade.

15. The manufacturing method for a light emitting diode according to claim 10,
wherein a size of an abrasive grain of the dicing blade is 2 μm or more.
